(19) United States
(12) Patent Application Publication
(10) Pub. No.: US 2022/0197134 A1
(43) Pub. Date: Jun. 23, 2022

(54) System and Method of Determining Shaping Parameters Based on Contact Line Motion

(71) Applicant: CANON KABUSHIKI KAISHA, Tokyo (JP)

(72) Inventor: Tomohiro Harayama, Austin, TX (US)

(21) Appl. No.: 17/132,048

(22) Filed: Dec. 23, 2020

(51) Int. Cl. G03F 7/00

(52) U.S. Cl. CPC G03F 7/0002

(57) ABSTRACT

Systems and methods of shaping a film and/or determining shaping conditions for shaping a film which may comprise: shaping a test film with a first set of shaping conditions; analyzing a time series of spread camera images obtained while shaping the test film to estimate a set of test film spreading characteristics; and creating an estimate of a probable reduction in non-fill defects based on the test film spreading characteristics.

### BACKGROUND OF INVENTION

### Technical Field

The present disclosure relates to systems and methods for determining shaping parameters. In particular for determining the shaping parameters based on contact line motion.

### Description of the Related Art

Nano-fabrication includes the fabrication of very small structures that have features on the order of 100 nanometers or smaller. One application in which nano-fabrication has had a sizeable impact is in the fabrication of integrated circuits. The semiconductor processing industry continues to strive for larger production yields while increasing the circuits per unit area formed on a substrate. Improvements in nano-fabrication include providing greater process control and/or improving throughput while also allowing continued reduction of the minimum feature dimensions of the structures formed.

One nano-fabrication technique in use today is commonly referred to as nanoimprint lithography. Nanoimprint lithography is useful in a variety of applications including, for example, fabricating one or more layers of integrated devices by shaping a film on a substrate. Examples of an integrated device include but are not limited to CMOS logic, microprocessors, NAND Flash memory, NOR Flash memory, DRAM memory, MRAM, 3D cross-point memory, Re-RAM, Fe-RAM, SU-RAM, MEMS, and the like. Exemplary nanoimprint lithography systems and processes are described in detail in numerous publications, such as U.S. Pat. No. 8,349,241, U.S. Pat. No. 8,066,930, and U.S. Pat. No. 6,936,194, all of which are hereby incorporated by reference herein.

The nanoimprint lithography technique disclosed in each of the aforementioned patents describes the shaping of a film on a substrate by the formation of a relief pattern in a formable material (polymerizable) layer. The shape of this film may then be used to transfer a pattern corresponding to the relief pattern into and/or onto an underlying substrate.

The shaping process uses a template spaced apart from the substrate. The formable liquid is applied onto the substrate. The template is brought into contact with the formable liquid that may have been deposited as a drop pattern causing the formable liquid to spread and fill the space between the template and the substrate. The formable liquid is solidified to form a film that has a shape (pattern) conforming to a shaping surface of the template. After solidification, the template is separated from the solidified layer such that the template and the substrate are spaced apart.

The substrate and the solidified layer may then be subjected to known steps and processes for device (article) fabrication, including, for example, curing, oxidation, layer formation, deposition, doping, planarization, etching, formable material removal, dicing, bonding, and packaging, and the like. For example, the pattern on the solidified layer may be subjected to an etching process that transfers the pattern into the substrate.

### SUMMARY OF THE INVENTION

A first embodiment, may be a method of shaping a film. The method may comprise: shaping the film with a template; analyzing a time series of images obtained by imaging the film while shaping the film to estimate film spreading characteristics; and creating an estimate of a probable reduction in non-fill defects based on the film spreading characteristics.

The first embodiment, may further comprise presenting the film spreading characteristics on a display device and the estimate of the probable reduction in non-fill defects.

The first embodiment, may further comprise determining a shaping condition based on the estimate of the probable reduction in non-fill defects.

The first embodiment, may be a method of manufacturing an article using the shaping method. The method of manufacturing the article may further comprise: shaping a device-yielding film on a device-yielding substrate with the determined shaping condition; processing the device-yielding substrate; and forming the article from the processed device-yielding substrate.

In an aspect of the first embodiment, shaping the test film may comprise: dispensing a drop pattern of drops of formable material onto a test substrate; and bowing out the template with an initial back pressure prior to an initial contact time. At the initial contact time, the bowed out template may be positioned at an initial contact position. At the initial contact time, a portion of the bowed out template may be in contact with a portion of the drops of formable material. During a first contact period, starting with the initial contact time, back pressure applied to the template may be reduced along a back pressure trajectory. During the first contact period, a force applied to the template may be reduced along a force trajectory. During a filling period, after the contact period, the back pressure and the force applied to the template may be held substantially constant. During a curing period, after the filling period, the formable material may be exposed to actinic radiation.

The first embodiment, may further comprise shaping a pair of preliminary test films. The pair of preliminary test films may include: a short fill time preliminary test film; and a long fill time preliminary test film. The short fill time preliminary test film may be shaped with a first subset of shaping conditions and a short fill time. The long fill time preliminary test film may be shaped with the first subset of shaping conditions and a long fill time. The first embodiment, may further comprise generating a pair of preliminary maps of non-fill defect density of the pair of preliminary test films. The pair of preliminary maps may include: a short fill time map; and a long fill time map. The first embodiment, may further comprise identifying a set of non-fill sensitive locations as locations in the pair of preliminary maps with a defect density above a threshold in the short fill time map and defect density below the threshold in the long fill time map; analyzing a preliminary series of images obtained by imaging the short fill time preliminary test film while shaping the short fill time preliminary test film to estimate a set of preliminary test film spreading characteristics; generating a correlation set comprising: the set of non-fill sensitive locations; and the set of preliminary test film spreading characteristics.

In an aspect of the first embodiment, a set of shaping conditions is used while shaping the film that is used for creating the estimate of the probable reduction in non-fill defects; the set of shaping conditions may include a first variation of the first subset of shaping conditions and the short fill time.

In an aspect of the first embodiment, creating the estimate of the probable reduction in non-fill defects comprises: calculating a set of spreading characteristic differences between a set of the test film spreading characteristics and the set of preliminary test film spreading characteristics at the set of non-fill sensitive locations.

In an aspect of the first embodiment, creating the set of preliminary test film spreading characteristics may comprise comparing the set of spreading characteristic differences to a threshold.

The first embodiment, may further comprise determining if the first variation is an improvement on the first subset of shaping conditions and the short fill time, based on the map of non-fill defect expected improvement.

In an aspect of the first embodiment, the first variation of the first subset of shaping conditions may include an adjustment of one or both of: an imprint force trajectory; and an imprint backpressure trajectory.

In an aspect of the first embodiment, generating pairs of preliminary maps may comprise: inspecting the short fill time preliminary test film to identify locations of non-fill defects which makes up the short fill time map; and inspecting the long fill time preliminary test film to identify locations of non-fill defects which makes up the long fill time map. The may further comprise: generating a short fill time radial histogram of defect density by azimuthally averaging defects in the short fill time map; and generating a long fill time radial histogram of defect density by azimuthally averaging defects in the long fill time map. The set of non-fill sensitive locations may be a set of non-fill sensitive radial regions in which a difference between the long fill time radial histogram and the short fill time radial histogram are above a defect density threshold. Generating the correlation set may comprise identifying a set of non-fill sensitive spread times based on the set of preliminary test film spreading characteristics that correspond to the set of non-fill sensitive radial regions.

In an aspect of the first embodiment, the set of preliminary test film spreading characteristics may include a preliminary time series of radially averaged estimated contact radii. Identifying the set of non-fill sensitive spread times may comprise identifying time periods in the time series of radially averaged estimated contact radii in which the radially averaged estimated contact radii are within the set of non-fill sensitive radial regions.

In an aspect of the first embodiment, a first set of shaping conditions is used for shaping the film that is used for creating the estimate of the probable reduction in non-fill defects; the first set of shaping conditions may include a variation of the first subset of shaping conditions. The variation may include an adjustment to one or both of a back pressure trajectory and a force trajectory in the first subset of shaping conditions during at least one time period in the set of non-fill sensitive spread times.

In an aspect of the first embodiment, the set of preliminary test film spreading characteristics may include a set of preliminary spread times correlated with a preliminary set of radially averaged estimated contact radii. The film spreading characteristics may include a set of test spread times correlated with a test set of radially averaged estimated contact radii. The method may further comprise calculating spread time differences between: the set of test spread times at the set of non-fill sensitive locations in the test set of radially averaged estimated contact radii; and the set of preliminary spread times at the set of non-fill sensitive locations in the preliminary set of radially averaged estimated contact radii. The estimate of the probable reduction in non-fill defects may be based on the spread time differences.

In an aspect of the first embodiment, the set of preliminary test film spreading characteristics may include a preliminary set of radially averaged estimated contact angles correlated with a preliminary set of radially averaged estimated contact radii. The film spreading characteristics may include a test set of radially averaged estimated contact angles correlated with a test set of radially averaged estimated contact radii. The method may further comprise calculating contact angle differences between: the test set of radially averaged estimated contact angles at the set of non-fill sensitive locations in the test set of radially averaged estimated contact radii; and the preliminary set of radially averaged estimated contact angles at the set of non-fill sensitive locations in the preliminary set of radially averaged estimated contact radii. The estimate of the probable reduction in non-fill defects is based on the contact angle differences.

A second embodiment, may be a method of determining shaping conditions for shaping a film comprising: (a) shaping a film in a plurality of fields with a plurality of shaping conditions including short spread times below a threshold and long spread times above the threshold; (b) analyzing the plurality of fields to identify a first set of locations in which non-fill defects appear during short spread times and do not appear during long spread times; (c) determining a first set of spread speeds and a first set of contact angles for each of the first set of location and for each of the plurality of shaping conditions by analyzing a time series of images obtained by imaging the film in the plurality of fields during the shaping of the plurality of fields; (d) shaping a film in a test field with a set of test shaping conditions; (e) determining a test set of spread speeds and a test set of contact angles for each of the first set of locations by analyzing a test series of images obtained by imaging the film in the test field during the shaping of the test field with the test shaping conditions; (f) determining a test expected improvement that there are one or more non-fill defects at the first set of locations based on: the test set of spread speeds; the test set of contact angles; the first set of spread speeds; and the first set of contact angles; and (g) repeat steps (d)-(f) with different test shaping conditions to identify test shaping conditions with the lowest test expected improvement as the shaping conditions.

A second embodiment, may be a shaping system control apparatus comprising: a memory; and a processor. The processor may be configured to: send a shaping condition to a shaping system, wherein the shaping system will shape a film with the shaping condition; receive a time series of images from the shaping system that were obtained by imaging the film while shaping the film and store the time series of images in the memory; analyze the time series of images to estimate a film spreading characteristics; and create an estimate of a probable reduction in non-fill defects based on the film spreading characteristics.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF THE FIGURES

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention and are therefore not to be considered limiting of its scope, for the invention may admit to other equally effective embodiments.

FIG. 1 is an illustration of an exemplary nanoimprint lithography system having a template with a mesa spaced apart from a substrate as used in an embodiment.

FIG. 2 is an illustration of an exemplary template that may be used in an embodiment.

FIG. 3 is a flowchart illustrating an exemplary imprinting method as used in an embodiment.

FIG. 4 is a micrograph of a non-fill defect as might be identified in an exemplary embodiment.

FIGS. 5A-B are maps of distribution of non-fill defect locations as might be generated in an exemplary embodiment.

FIG. 5C illustrates histograms of defect counts as might be generated in an embodiment.

FIG. 5D illustrates a shaping field, divided up into radial bins as might be used to generate histograms in an embodiment.

FIG. 5E is a chart illustrating the variation in area of the bins in FIG. 5D as might be used for normalizing the information in FIG. 5C as might be used in an embodiment.

FIGS. 6A-B are flowcharts illustrating methods which might be implemented in an embodiment.

FIG. 7 is a series of spread camera images as might be generated in an exemplary embodiment.

FIG. 8 is a diagram illustrated the relationship between fringes in the spread camera images to the shape of the template as might be used in an embodiment.

FIGS. 9A-D are illustrations showing the shape of the template may take on during the contacting period in an exemplary embodiment.

FIGS. 10A-B are charts illustrating exemplary force trajectories as might be used in an exemplary embodiment.

FIGS. 11-A-D are charts of spreading characteristics as might generated in exemplary embodiment.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

The nanoimprint lithography technique can be used to shape a film on a substrate from a formable material. The shaping process is performed during a contact period followed by a curing period. Prior to the contact period a shaping surface (patterning surface or planarization surface) of a template (or superstrate) is bowed out. During the contact period, the bowed out shaping surface is brought into contact with formable material on a substrate. The shaping surface is then flattened out. After the contact period the formable material is exposed to actinic radiation which causes the formable material to cure. During the contact period gas between the shaping surface and the substrate escapes. Gas that is still between the shaping surface and the substrate when the curing period starts can cause non-fill defects.

Minimizing the number of non-fill defects while increasing throughput improves the performance of the nanoimprint lithography technique. Minimizing the number of non-fill defects includes determining shaping parameters which minimizes the number of non-fill defects. There are numerous shaping parameters which affect how the shaping surface is controlled during the contact period. Prior art methods of determining these shaping parameters includes performing experiments with different shaping parameters and inspecting the shaped film produced by these experiments to identify non-fill defects. Determining these shaping parameters is a time and resource intensive process. The applicant has found systems and method that reduce the time and resources required for determining these shaping parameters.

### Shaping System

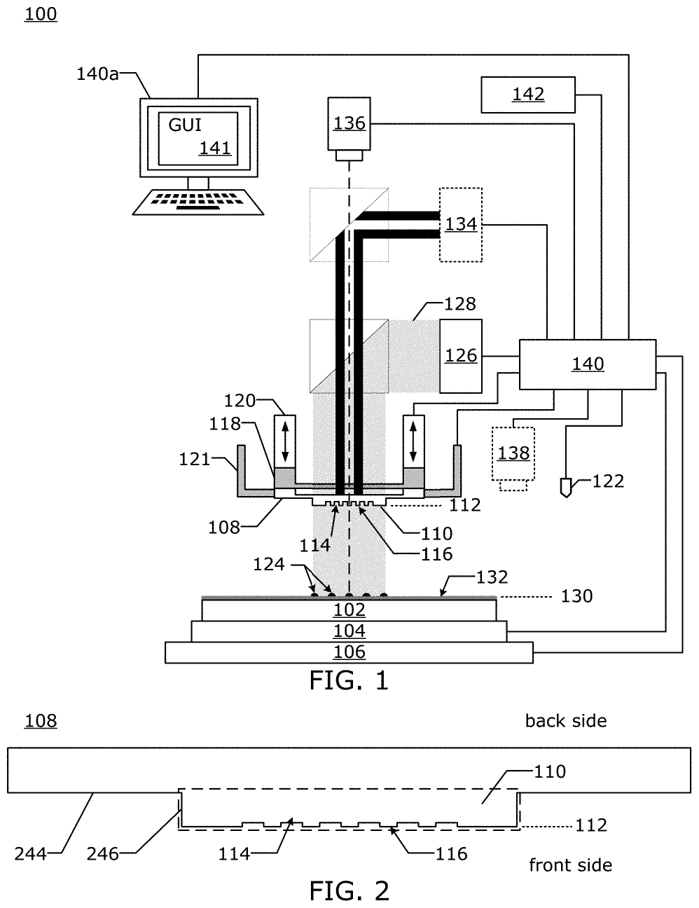

FIG. 1 is an illustration of a shaping system 100 (for example a nanoimprint lithography system or inkjet adaptive planarization system) in which an embodiment may be implemented. The shaping system 100 is used to produce an imprinted (shaped) film on a substrate 102. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the positional axes x, y, and z, and rotational axes θ, ψ, and φ. The substrate positioning stage 106, the substrate 102, and the substrate chuck 104 may also be positioned on a base (not shown). The substrate positioning stage may be a part of a positioning system. In an alternative embodiment, the substrate chuck 104 may be attached to the base.

Spaced-apart from the substrate 102 is a template 108 (also referred to as a superstrate). The template 108 may include a body having a mesa (also referred to as a mold) 110 extending towards the substrate 102 on a front side of the template 108. The mesa 110 may have a shaping surface 112 thereon also on the front side of the template 108. The shaping surface 112, also known as a patterning surface, is the surface of the template that shapes the formable material 124. In an embodiment, the shaping surface 112 is planar and is used to planarize the formable material. Alternatively, the template 108 may be formed without the mesa 110, in which case the surface of the template facing the substrate 102 is equivalent to the mesa 110 and the shaping surface 112 is that surface of the template 108 facing the substrate 102.

The template 108 may be formed from such materials including, but not limited to, fused-silica, quartz, silicon, organic polymers, siloxane polymers, borosilicate glass, fluorocarbon polymers, metal, hardened sapphire, and/or the like. The shaping surface 112 may have features defined by a plurality of spaced-apart template recesses 114 and/or template protrusions 116. The shaping surface 112 defines a pattern that forms the basis of a pattern to be formed on the substrate 102. In an alternative embodiment, the shaping surface 112 is featureless in which case a planar surface is formed on the substrate. In an alternative embodiment, the shaping surface 112 is featureless and the same size as the substrate and a planar surface is formed across the entire substrate.

Template 108 may be coupled to a template chuck 118. The template chuck 118 may be, but is not limited to, vacuum chuck, pin-type chuck, groove-type chuck, electrostatic chuck, electromagnetic chuck, and/or other similar chuck types. The template chuck 118 may be configured to apply stress, pressure, and/or strain to template 108 that varies across the template 108. The template chuck 118 may include a template magnification control system 121. The template magnification control system 121 may include piezoelectric actuators (or other actuators) which can squeeze and/or stretch different portions of the template 108. The template chuck 118 may include a system such as a zone based vacuum chuck, an actuator array, a pressure bladder, etc. which can apply a pressure differential to a back surface of the template causing the template to bend and deform.

The template chuck 118 may be coupled to a shaping head 120 which is a part of the positioning system. The shaping head 120 may be moveably coupled to a bridge. The shaping head 120 may include one or more actuators such as voice coil motors, piezoelectric motors, linear motor, nut and screw motor, etc., which are configured to move the template chuck 118 relative to the substrate in at least the z-axis direction, and potentially other directions (e.g. positional axes x, and y, and rotational axes θ, ψ, and φ).

The shaping system 100 may further comprise a fluid dispenser 122. The fluid dispenser 122 may also be moveably coupled to the bridge. In an embodiment, the fluid dispenser 122 and the shaping head 120 share one or more or all of the positioning components. In an alternative embodiment, the fluid dispenser 122 and the shaping head 120 move independently from each other. The fluid dispenser 122 may be used to deposit liquid formable material 124 (e.g., polymerizable material) onto the substrate 102 in a drop pattern. Additional formable material 124 may also be added to the substrate 102 using techniques, such as, drop dispense, spin-coating, dip coating, chemical vapor deposition (CVD), physical vapor deposition (PVD), thin film deposition, thick film deposition, and/or the like prior to the formable material 124 being deposited onto the substrate 102. The formable material 124 may be dispensed upon the substrate 102 before and/or after a desired volume is defined between the shaping surface 112 and the substrate 102 depending on design considerations. The formable material 124 may comprise a mixture including a monomer as described in U.S. Pat. No. 7,157,036 and U.S. Pat. No. 8,076,386, both of which are herein incorporated by reference.

Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that induces a phase change in the liquid formable material into a solid material whose top surface is determined by the shape of the shaping surface 112. The curing system may include at least a radiation source 126 that directs actinic energy along an exposure path 128. The shaping head and the substrate positioning stage 106 may be configured to position the template 108 and the substrate 102 in superimposition with the exposure path 128. The radiation source 126 sends the actinic energy along the exposure path 128 after the template 108 has contacted the formable material 128. FIG. 1 illustrates the exposure path 128 when the template 108 is not in contact with the formable material 124, this is done for illustrative purposes so that the relative position of the individual components can be easily identified. An individual skilled in the art would understand that exposure path 128 would not substantially change when the template 108 is brought into contact with the formable material 124. In an embodiment, the actinic energy may be directed through both the template chuck 118 and the template 108 into the formable material 124 under the template 108. In an embodiment, the actinic energy produced by the radiation source 126 is UV light that induces polymerization of monomers in the formable material 124.

The shaping system 100 may further comprise a field camera 136 that is positioned to view the spread of formable material 124 after the template 108 has made contact with the formable material 124. FIG. 1 illustrates an optical axis of the field camera's imaging field as a dashed line. As illustrated in FIG. 1 the shaping system 100 may include one or more optical components (dichroic mirrors, beam combiners, prisms, lenses, mirrors, etc.) which combine the actinic radiation with light to be detected by the field camera. The field camera 136 may be configured to detect the spread of formable material under the template 108. The optical axis of the field camera 136 as illustrated in FIG. 1 is straight but may be bent by one or more optical components. The field camera 136 may include one or more of: a CCD; a sensor array; a line camera; and a photodetector which are configured to gather light that has a wavelength that shows a contrast between regions underneath the template 108 that are in contact with the formable material, and regions underneath the template 108 which are not in contact with the formable material 124. The field camera 136 may be configured to gather monochromatic images of visible light. The field camera 136 may be configured to provide images of the spread of formable material 124 underneath the template 108; the separation of the template 108 from cured formable material; and can be used to keep track of the imprinting (shaping) process. The field camera 136 may also be configured to measure interference fringes, which change as the formable material spreads 124 between the gap between the shaping surface 112 and the substrate surface 130.

The shaping system 100 may further comprise a droplet inspection system 138 that is separate from the field camera 136. The droplet inspection system 138 may include one or more of a CCD, a camera, a line camera, and a photodetector. The droplet inspection system 138 may include one or more optical components such as lenses, mirrors, apertures, filters, prisms, polarizers, windows, adaptive optics, and/or light sources. The droplet inspection system 138 may be positioned to inspect droplets prior to the shaping surface 112 contacting the formable material 124 on the substrate 102. In an alternative embodiment, the field camera 136 may be configured as a droplet inspection system 138 and used prior to the shaping surface 112 contacting the formable material 124

The shaping system 100 may further include a thermal radiation source 134 which may be configured to provide a spatial distribution of thermal radiation to one or both of the template 108 and the substrate 102. The thermal radiation source 134 may include one or more sources of thermal electromagnetic radiation that will heat up one or both of the substrate 102 and the template 108 and does not cause the formable material 124 to solidify. The thermal radiation source 134 may include a SLM such as a digital micromirror device (DMD), Liquid Crystal on Silicon (LCoS), Liquid Crystal Device (LCD), etc., to modulate the spatio-temporal distribution of thermal radiation. The shaping system 100 may further comprise one or more optical components which are used to combine the actinic radiation, the thermal radiation, and the radiation gathered by the field camera 136 onto a single optical path that intersects with the imprint field when the template 108 comes into contact with the formable material 124 on the substrate 102. The thermal radiation source 134 may send the thermal radiation along a thermal radiation path (which in FIG. 1 is illustrated as 2 thick dark lines) after the template 108 has contacted the formable material 128. FIG. 1 illustrates the thermal radiation path when the template 108 is not in contact with the formable material 124, this is done for illustrative purposes so that the relative position of the individual components can be easily identified. An individual skilled in the art would understand that the thermal radiation path would not substantially change when the template 108 is brought into contact with the formable material 124. In FIG. 1 the thermal radiation path is shown terminating at the template 108, but it may also terminate at the substrate 102. In an alternative embodiment, the thermal radiation source 134 is underneath the substrate 102, and thermal radiation path is not combined with the actinic radiation and the visible light.

Prior to the formable material 124 being dispensed onto the substrate, a substrate coating 132 may be applied to the substrate 102. In an embodiment, the substrate coating 132 may be an adhesion layer. In an embodiment, the substrate coating 132 may be applied to the substrate 102 prior to the substrate being loaded onto the substrate chuck 104. In an alternative embodiment, the substrate coating 132 may be applied to substrate 102 while the substrate 102 is on the substrate chuck 104. In an embodiment, the substrate coating 132 may be applied by spin coating, dip coating, drop dispense, slot dispense, etc. In an embodiment, the substrate 102 may be a semiconductor wafer. In another embodiment, the substrate 102 may be a blank template (replica blank) that may be used to create a daughter template after being imprinted.

The shaping system 100 may include an imprint field atmosphere control system such as gas and/or vacuum system, an example of which is described in U.S. Patent Publication Nos. 2010/0096764 and 2019/0101823 which are hereby incorporated by reference. The gas and/or vacuum system may include one or more of pumps, valves, solenoids, gas sources, gas tubing, etc. which are configured to cause one or more different gases to flow at different times and different regions. The gas and/or vacuum system may be connected to a first gas transport system that transports gas to and from the edge of the substrate 102 and controls the imprint field atmosphere by controlling the flow of gas at the edge of the substrate 102. The gas and/or vacuum system may be connected to a second gas transport system that transports gas to and from the edge of the template 108 and controls the imprint field atmosphere by controlling the flow of gas at the edge of the template 108. The gas and/or vacuum system may be connected to a third gas transport system that transports gas to and from the top of the template 108 and controls the imprint field atmosphere by controlling the flow of gas through the template 108. One or more of the first, second, and third gas transport systems may be used in combination or separately to control the flow of gas in and around the imprint field.

The shaping system 100 may be regulated, controlled, and/or directed by one or more processors 140 (controller) in communication with one or more components and/or subsystems such as the substrate chuck 104, the substrate positioning stage 106, the template chuck 118, the shaping head 120, the fluid dispenser 122, the radiation source 126, the thermal radiation source 134, the field camera 136, imprint field atmosphere control system, and/or the droplet inspection system 138. The processor 140 may operate based on instructions in a computer readable program stored in a non-transitory computer readable memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The controller 140 may include a plurality of processors that are both included in the shaping system 100a and in communication with the shaping system 100a. The processor 140 may be in communication with a networked computer 140a on which analysis is performed and control files such as a drop pattern are generated. In an embodiment, there are one or more graphical user interface (GUI) 141 on one or both of the networked computer 140a and a display in communication with the processor 140 which are presented to an operator and/or user.

Either the shaping head 120, the substrate positioning stage 106, or both varies a distance between the mold 110 and the substrate 102 to define a desired space (a bounded physical extent in three dimensions) that is filled with the formable material 124. For example, the shaping head 120 may apply a force to the template 108 such that mold 110 is in contact with the formable material 124. After the desired volume is filled with the formable material 124, the radiation source 126 produces actinic radiation (e.g. UV, 248 nm, 280 nm, 350 nm, 365 nm, 395 nm, 400 nm, 405 nm, 435 nm, etc.) causing formable material 124 to cure, solidify, and/or cross-link; conforming to a shape of the substrate surface 130 and the shaping surface 112, defining a patterned layer on the substrate 102. The formable material 124 is cured while the template 108 is in contact with formable material 124, forming the patterned layer on the substrate 102. Thus, the shaping system 100 uses a shaping process to form the patterned layer which has recesses and protrusions which are an inverse of the pattern in the shaping surface 112. In an alternative embodiment, the shaping system 100 uses a shaping process to form a planar layer with a featureless shaping surface 112.

The shaping process may be done repeatedly in a plurality of imprint fields (also known as just fields or shots) that are spread across the substrate surface 130. Each of the imprint fields may be the same size as the mesa 110 or just the pattern area of the mesa 110. The pattern area of the mesa 110 is a region of the shaping surface 112 which is used to imprint patterns on a substrate 102 which are features of the device or are then used in subsequent processes to form features of the device. The pattern area of the mesa 110 may or may not include mass velocity variation features (fluid control features) which are used to prevent extrusions from forming on imprint field edges. In an alternative embodiment, the substrate 102 has only one imprint field which is the same size as the substrate 102 or the area of the substrate 102 which is to be patterned with the mesa 110. In an alternative embodiment, the imprint fields overlap. Some of the imprint fields may be partial imprint fields which intersect with a boundary of the substrate 102.

The patterned layer may be formed such that it has a residual layer having a residual layer thickness (RLT) that is a minimum thickness of formable material 124 between the substrate surface 130 and the shaping surface 112 in each imprint field. The patterned layer may also include one or more features such as protrusions which extend above the residual layer having a thickness. These protrusions match the recesses 114 in the mesa 110.

### Template

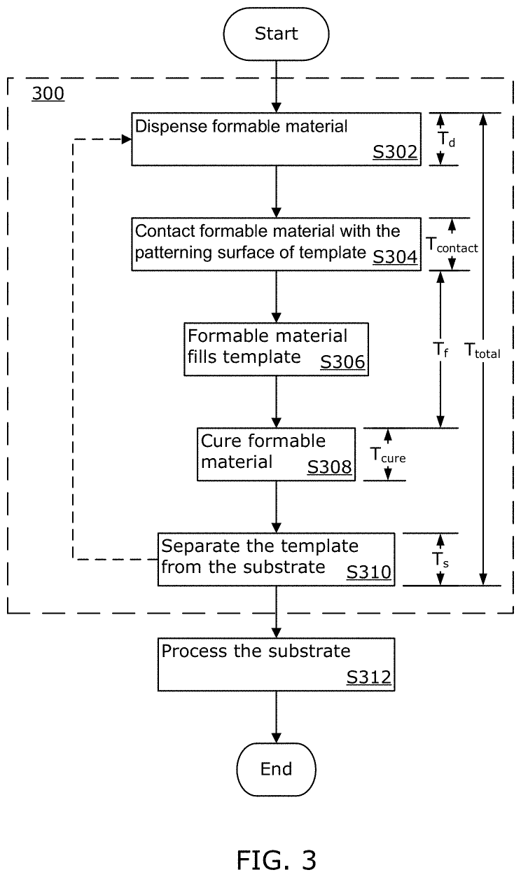

FIG. 2 is an illustration of a template 108 (not to scale) that may be used in an embodiment. The shaping surface 112 may be on a mesa 110 (identified by the dashed box in FIG. 2). The mesa 110 is surrounded by a recessed surface 244 on the front side of the template. Mesa sidewalls 246 connect the recessed surface 244 to shaping surface 112 of the mesa 110. The mesa sidewalls 246 surround the mesa 110. In an embodiment in which the mesa is round or has rounded corners, the mesa sidewalls 246 refers to a single mesa sidewall that is a continuous wall without corners. In an embodiment, the mesa sidewalls 246 may have one or more of a perpendicular profile; an angled profile; a curved profile; a staircase profile; a sigmoid profile; a convex profile; or a profile that is combination of those profiles.

### Shaping Process

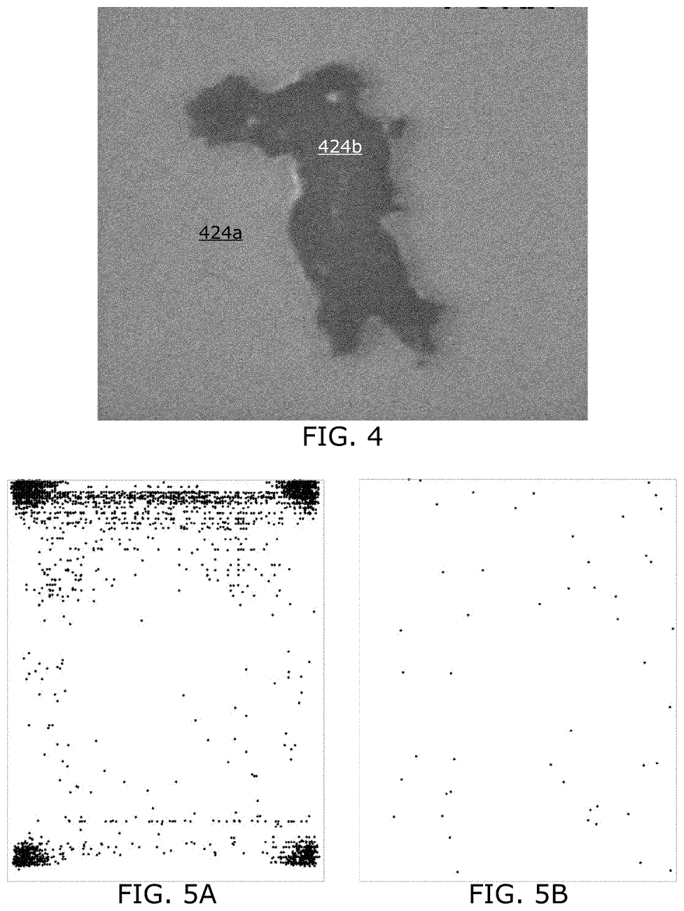

FIG. 3 is a flowchart of a method of manufacturing an article (device) that includes a shaping process 300 performed by the shaping system 100. The shaping process 300 can be used to form patterns in formable material 124 on one or more imprint fields (also referred to as: pattern areas or shot areas). The shaping process 300 may be performed repeatedly on a plurality of substrates 102 by the shaping system 100. The processor 140 may be used to control the shaping process 300.

In an alternative embodiment, the shaping process 300 is used to planarize the substrate 102. In which case, the shaping surface 112 is featureless and may also be the same size or larger than the substrate 102.

The beginning of the shaping process 300 may include a template mounting step causing a template conveyance mechanism to mount a template 108 onto the template chuck 118. The shaping process 300 may also include a substrate mounting step, the processor 140 may cause a substrate conveyance mechanism to mount the substrate 102 onto the substrate chuck 104. The substrate may have one or more coatings and/or structures. The order in which the template 108 and the substrate 102 are mounted onto the shaping system 100 is not particularly limited, and the template 108 and the substrate 102 may be mounted sequentially or simultaneously.

In a positioning step, the processor 140 may cause one or both of the substrate positioning stage 106 and/or a dispenser positioning stage to move an imprinting field i (index i may be initially set to 1) of the substrate 102 to a fluid dispense position below the fluid dispenser 122. The substrate 102, may be divided into N imprinting fields, wherein each imprinting field is identified by a shaping field index i. In which N is the number of shaping fields and is a real positive integer such as 1, 10, 62, 75, 84, 100, etc. {N∈ [symbol] ⁺}. In a dispensing step S302, the processor 140 may cause the fluid dispenser 122 to dispense formable material based on a drop pattern onto an imprinting field. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The imprint field may be moved relative to the fluid dispenser 122 while the fluid dispenser is ejecting formable material 124. Thus, the time at which some of the droplets land on the substrate may vary across the imprint field i. The dispensing step S302 may be performed during a dispensing period T_{d} for each imprint field i.

In an embodiment, during the dispensing step S302, the formable material 124 is dispensed onto the substrate 102 in accordance with a drop pattern. The drop pattern may include information such as one or more of position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets.

After, the droplets are dispensed, then a contacting step S304 may be initiated, the processor 140 may cause one or both of the substrate positioning stage 106 and a template positioning stage to bring the shaping surface 112 of the template 108 into contact with the formable material 124 in a particular imprint field. The contacting step S304 may be performed during a contacting period T_{contact} which starts after the dispensing period T_{d} and begins with the initial contact of the shaping surface 112 with the formable material 124. In an embodiment, at the beginning of the contact period T_{contact} the template chuck 118 is configured to bow out the template 108 so that only a portion of the shaping surface 112 is in contact with a portion of the formable material. In an embodiment, the contact period T_{contact} ends when the template 108 is no longer bowed out by the template chuck 118. The degree to which the shaping surface 112 is bowed out relative to the substrate surface 130 may be estimated with the spread camera 136. The spread camera 136 may be configured to record interference fringes due to reflectance from at least the shaping surface 112 and the substrate surface 130. The greater the distance between neighboring interference fringes, the larger the degree to which the shaping surface 112 is bowed out.

During a filling step S306, the formable material 124 spreads out towards the edge of the imprint field and the mesa sidewalls 246. The edge of the imprint field may be defined by the mesa sidewalls 246. How the formable material 124 spreads and fills the mesa may be observed via the field camera 136 and may be used to track a progress of a fluid front of formable material. In an embodiment, the filling step S306 occurs during a filling period T_{f}. The filling period T_{f} begins when the contacting step S304 ends. The filling period T_{f} ends with the start of a curing period T_{c}. In an embodiment, during the filling period T_{f} the back pressure and the force applied to the template are held substantially constant. Substantially constant in the present context means that the back pressure variation and the force variation is within the control tolerances of the shaping system 100 which may be less 0.1% of the set point values.

In a curing step S308, the processor 140 may send instructions to the radiation source 126 to send a curing illumination pattern of actinic radiation through the template 108, the mesa 110, and the shaping surface 112 during a curing period T_{c}. The curing illumination pattern provides enough energy to cure (polymerize) the formable material 124 under the shaping surface 112. The curing period T_{c} is a period in which the formable material under the template receives actinic radiation with an intensity that is high enough to solidify (cure) the formable material. In an alternative embodiment, the formable material 124 is exposed to a gelling illumination pattern of actinic radiation before the curing period T_{c} which does not cure the formable material but does increase the viscosity of the formable material.

In a separation step S310, the processor 140 uses one or more of the substrate chuck 104, the substrate positioning stage 106, template chuck 118, and the shaping head 120 to separate the shaping surface 112 of the template 108 from the cured formable material on the substrate 102 during a separation period Tₛ. If there are additional imprint fields to be imprinted, then the process moves back to step S302. In an alternative embodiment, during step S302 two or more imprint fields receive formable material 124 and the process moves back to steps S302 or S304.

In an embodiment, after the shaping process 300 is finished additional semiconductor manufacturing processing is performed on the substrate 102 in a processing step S312 so as to create an article of manufacture (e.g. semiconductor device). In an embodiment, each imprint field includes a plurality of devices.

The further semiconductor manufacturing processing in processing step S312 may include etching processes to transfer a relief image into the substrate that corresponds to the pattern in the patterned layer or an inverse of that pattern. The further processing in processing step S312 may also include known steps and processes for article fabrication, including, for example, inspection, curing, oxidation, layer formation, deposition, doping, planarization, etching, formable material removal, dicing, bonding, packaging, mounting, circuit board assembly, and the like. The substrate 102 may be processed to produce a plurality of articles (devices).

### Non-Fill Defects

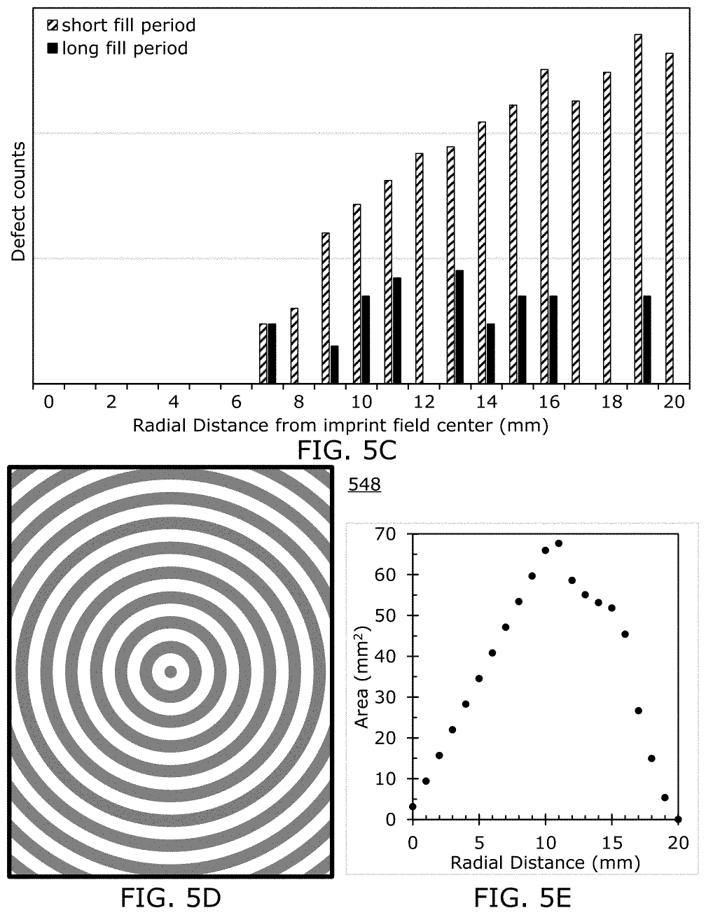

FIG. 4 is a micrograph of a cured formable material 424a on a substrate 102 with a non-fill defect 424b. A non-fill defect is a type defect that may occur during the shaping process 300. These non-fill defects may be found by inspecting the cured formable material with a microscope, a profilometer, an automated inspection tool (for example the WI-2200 Wafer Inspector previously sold by KLA-Tencor Corporation, Milpitas, Calif.), an atomic force microscope, or another device which is capable of inspecting small features on a substrate. Non-fill defects can occur when the formable material 124 does not have time to fill a particular region under the shaping surface 112. In other words, gas trapped under the shaping surface 112 does not have time to escape before the curing step S308.

Two goals of the shaping process 300 are to minimize the number of non-fill defects in the cured formable material 424a and to minimize the total shaping time (Tₜₒₜₐₗ) used to perform the shaping process 300. These are conflicting goals. Optimizing the shaping process 300 includes modifying the shaping conditions such that number of non-fill defects is below a non-fill defects threshold and the total shaping time Tₜₒₜₐₗ is below a target total shaping time. In the prior art this is accomplished by shaping a plurality of substrates with a plurality of shaping conditions and then inspecting the cured formable material on each of the substrates to identify non-fill defects.

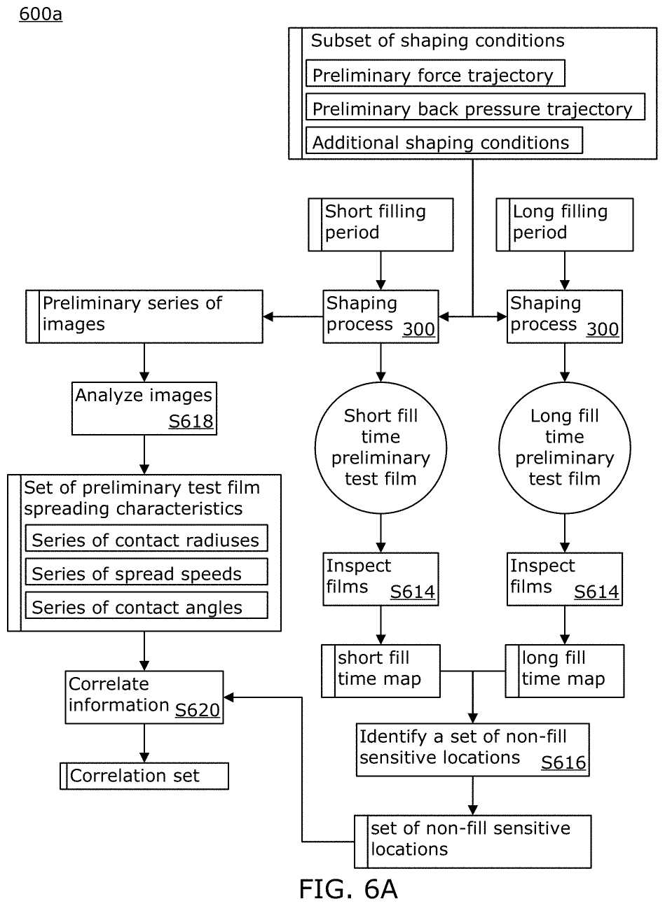

The applicant has found that certain regions of the substrate are more sensitive to non-fill defects than other regions of the substrate when the filling period T_{f} is short. When the filling period T_{f} is longer than non-fill defects in these locations disappear are less likely to occur. FIG. 5A is experimental data of a distribution of non-fill defect locations when the filling period T_{f} is short. FIG. 5B is experimental data of a distribution of non-fill defect locations when the filling period T_{f} is long. In the present context long filling period is at least twice as long as a short filling period.

The applicant has determined that there is often a radial signature in the non-fill data. This radial signature of the non-fill data can be characterized with a radial histogram as illustrated by the long filling period radial histogram and the short filling period radial histogram illustrated in the log scale (y axis) histograms in FIG. 5C.

The substrate 120, may be divided into a plurality of shaping fields 548. The shaping field 548 may take on any shape for example: a rectangle; a polygon; or a shape with one or more linear edges and one or more curved edges. The shaping field 584 may be divided into a plurality of radial bins as illustrated by the alternating grey and white bins in FIG. 5D. These radial bins may be inscribed within the shaping field as shown in FIG. 5D. The defect counts may be normalized based on the unit areas (as shown in FIG. 5E) of the radial ring bins intersection with the shaping field 584. The radial histogram may be formed by azimuthally averaging defects in each the long fill time map over the area of the radial ring that intersects with shaping field 584.

During the contacting step S304, the shaping surface 112 starts touching formable material from the center of the shaping field 584, and then spreads to the edge in a radial manner. A radial distribution of defects may be created during dynamic spread of formable material that occurs during the contacting step S304. If the filling step S306 is to short these defects will remain. In other words, the radial distribution of defects will reduce if the filling step S306 is long enough.

Dynamic spread may be controlled by controlling the force trajectory and template back pressure trajectory during the contacting step S306. The applicant has experimentally confirmed that changing the force trajectory and the template back pressure trajectory has affect radial distribution of non-fill defects. Previously, finding a good set of shaping conditions (for example force trajectory, back pressure trajectory) includes an iterative process of: shaping test films with a test set of shaping conditions; inspecting cured test films to detect sub-micron non-fill defects, and then repeating the process with a new set of test set of shaping conditions until non-fill defects are below a threshold. This iterative process is time and resource intensive process. The applicant has discovered an improved process which takes less time, less resources, and allows faster process of determining a good set of shaping conditions.

### Optimization Process

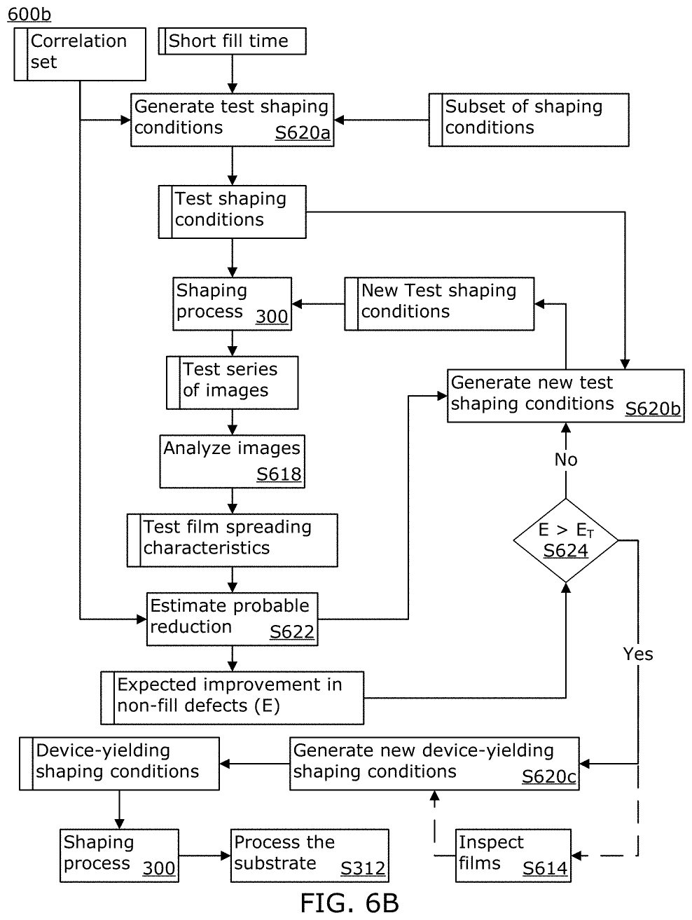

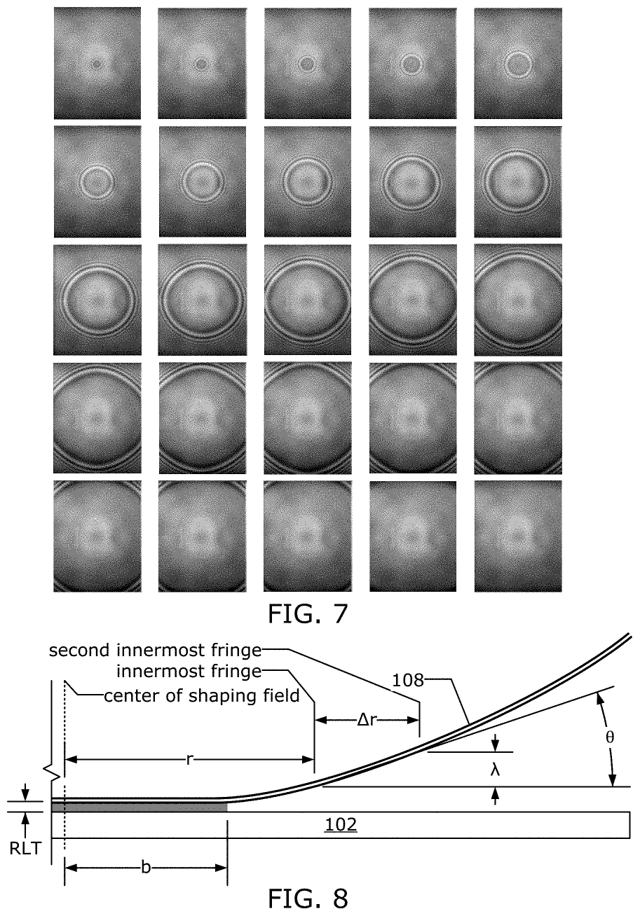

FIGS. 6A is an illustration of a correlation set generation process 600a. FIG. 6B is an illustration of shaping condition optimization process 600b that makes use of the correlation set. The correlation set generation process 600a may include forming a pair of preliminary test films using the shaping process 300. The shaping process 300 is performed using a subset of shaping conditions and long filling period for forming a long fill time preliminary test film. and a short filling period. The shaping process 300 is also performed using the subset of shaping conditions and short filling period for forming a short fill time preliminary test film. and a short filling period. During the shaping process 300 a preliminary series of images (spread camera images) are generated during the contacting period. The preliminary series of images may be obtained with the spread camera and may include interference fringes due to reflectance from at least the shaping surface 112 and the substrate surface 130. FIG. 7 is an example of preliminary series of images generated during the contacting period T_{contact} of the shaping process 300 when forming the short fill time preliminary test film.

The correlation set generation process 600a may include an inspection step S614 in which films are inspected to form defect maps. The inspection step S614 is performed twice to form a pair of preliminary maps of non-fill defect density. The inspection step S614 may generate a short fill time map (see FIG. 5A) based on inspecting the short fill time preliminary test film. The inspection step S614 may also generate a long fill time map (see FIG. 5B) based on inspecting the long fill time preliminary test film. The inspection step S614 may be performed using a microscope, a profilometer, an automated inspection tool (for example the WI-2200 Wafer Inspector previously sold by KLA-Tencor Corporation, Milpitas, Calif.), an atomic force microscope, or another device which is capable of inspecting small features in a cured film of formable material on a substrate.

The correlation set generation process 600a may include an identification step S616 to identify a set of non-fill sensitive locations. The identification step S616 includes identifying non-fill defect locations in the short fill time map and are not identified as defects in the short fill time map. These identified locations are probably non-fill sensitive locations. In an embodiment, this identification step S616 is done in a statistical manner in which defects are azimuthally summed and binned over a specific radius to form histograms such as those illustrated in FIG. 5C. For example, the non-fill sensitive locations are from 9-20 mm in FIG. 5C. In an embodiment, this identification step S616 is done in a statistical manner in which defects are azimuthally averaged and binned over a specific radius to form histograms. In an embodiment, this identification step S616 is done in a statistical manner in which defects are azimuthally averaged, binned over a specific radius, and normalized over the averaging area to form histograms. In an embodiment, this identification step S616 is done in a statistical manner in which defects are azimuthally averaged binned over a specific radius, normalized over the averaging area to form histograms, and the difference compared to a threshold.

The correlation set generation process 600a may include an analyzing images step S618 to estimate a set of preliminary test film spreading characteristics. The analyzing images step S618 may include analyzing a preliminary series of images obtained during the contacting period T_{contact} when forming the short fill time preliminary test film. As illustrated in FIG. 7 the preliminary series of images include interference fringes. Analysis of these interference fringes can be used to characterize the spreading of formable material under the shaping surface 112. A major influence on the interference fringes are interferences form reflections from the shaping surface 112 and substrate surface 130.

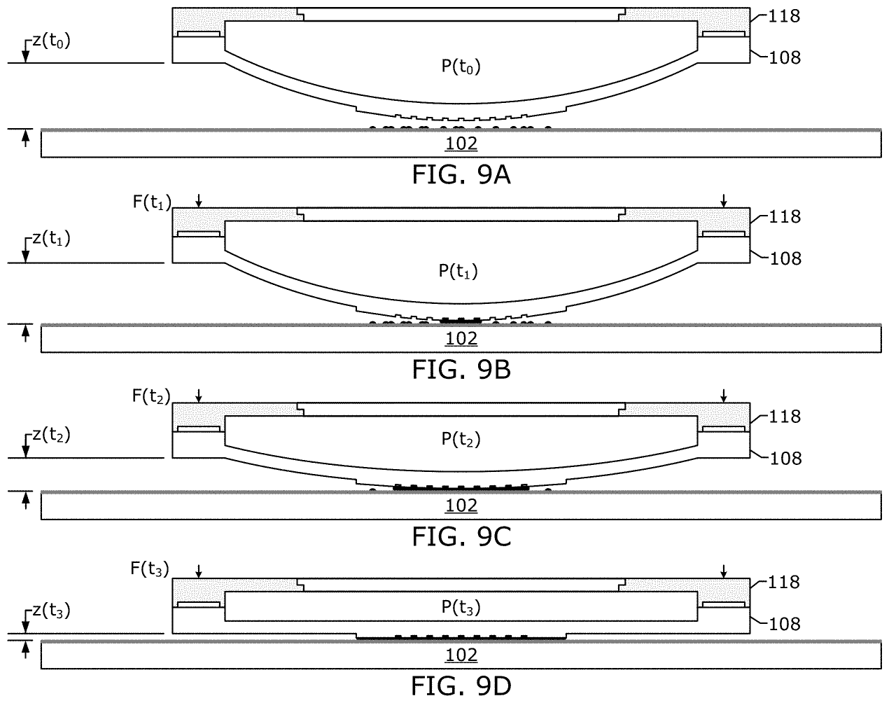

During the contacting period T_{contact} the contact angle θ decreases as the contact radius b increases. The position of the innermost fringe r is a reasonable estimate of the contact radius b when the RLT is less than the measurement wavelength λ as illustrate by FIG. 8. The set of preliminary test film spreading characteristics may include a time series of the contact radius b(t) as estimated by a time series of the innermost fringe radii r(t). The time series of innermost fringe radii r(t) may be inverted to give a series of spread times t_{spread}(r) as function of radius. The set of preliminary test film spreading characteristics may include the series of spread times t_{spread}(r) as function of radius. The set of preliminary test film spreading characteristics may include a time series of the spread speed v(t) of the contact radius as estimated by the time derivative of the time series of innermost fringe radii (v(t)=dr/dt). The set of preliminary test film spreading characteristics may include a radial series of the spread speed v(r) as function of the innermost fringe radius.

A fringe difference Δr between the second innermost fringe and the first innermost fringe is related to the contact angle θ and the measurement wavelength λ as described by equation (1) below and FIG. 8. The set of preliminary test film spreading characteristics may include a time series of the fringe difference Δr(t). The set of preliminary test film spreading characteristics may include a time series of the contact angle θ(t). The set of preliminary test film spreading characteristics may include a time series of the time derivative of the contact angle (ω(t)=dθ/dt). The set of preliminary test film spreading characteristics may include a radial series of the time derivative of the contact angle (ω(r)=dθ/dt).

$$θ = {tan}^{- 1} \frac{λ}{Δ r} \qquad ( 1 )$$

The correlation set generation process 600a may include a generating correlation set step S620. The generating correlation set step S620 may include correlating the set of preliminary test film spreading characteristics with the non-fill sensitive locations. The generating correlation set step S620 may include associating one or more values of the spreading characteristics particular non-fill sensitive locations. The generating correlation set step S620 may include determining a set of non-fill sensitive radii based on the set of non-fill sensitive locations. The generating correlation set step S620 may include associating non-fill sensitive radii with the set of preliminary test film.

The shaping condition optimization process 600b illustrated in FIG. 6B may include a test shaping conditions generation step S620a for generating test shaping condition. The test shaping conditions generation step S620a generated based on the correlation set, the short fill time, and the subset of shaping conditions. The test shaping conditions generation step S620a includes adjusting one or more of the subsets of shaping conditions. The shaping conditions which may be adjusted includes one or more of the: force trajectory during the contacting period T_{contact}; and the back pressure trajectory during the contacting period T_{contact}. The force trajectory or the back pressure trajectory may be adjusted during periods of time that is determined based on the correlation set.

The shaping condition optimization process 600b may include shaping a test film with the shaping process 300 using the test shaping conditions. A test time series of images may be generated during the shaping process 300. The shaping condition optimization process 600b may include analyzing images step S618 as described above but for the test time series of images to generate test film spreading characteristics. The test time series of images may be obtained with the spread camera and may include interference fringes due to reflectance from at least the shaping surface 112 and the substrate surface 130.

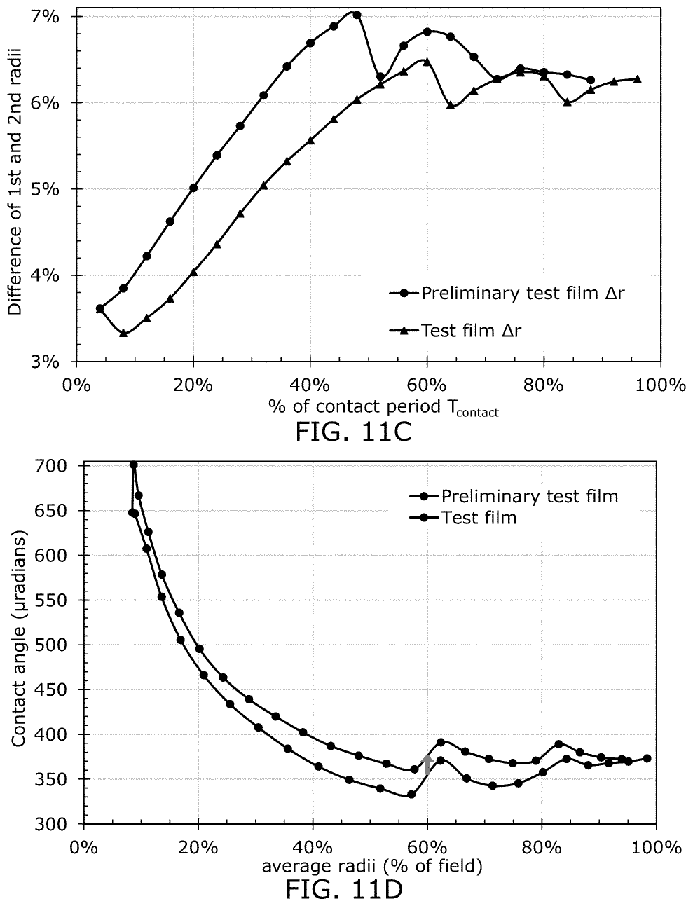

The shaping condition optimization process 600b may include an estimating reduction step S622 in which the expected improvement E that non-fill defects are reduced is estimated. The estimating reduction step S622 is performed by comparing the set of test film spreading characteristics to the set of preliminary test film spreading characteristics at the set of non-fill locations as illustrated in FIGS. 11A-D which may be displayed in GUI 141 on display that is connected to the shaping system 100 or on a computer that receives information from the shaping system 100.

The shaping condition optimization process 600b may include a comparison step S624 in which the expected improvement E is compared to an expected improvement threshold E_{T}. The expected improvement E and expected improvement threshold E_{T} may vary over the shaping field. The expected improvement E and expected improvement threshold E_{T} may have a radial variation over the shaping field. If the expected improvement E is not greater than a threshold than a generation of new test shaping conditions step S620b is performed. The generation of new test shaping conditions step S620b may generate a variation on the set of test shaping conditions that were previously used in which the force trajectory and/or the pressure trajectory is adjusted. If the expected improvement E is greater than a threshold than a set of device-yielding shaping conditions may be generated in a generation step S620c. Prior to or during the generation step S620c the test film may be inspected in an inspection step S614 to confirm that the expected improvement E is correct. If the expected improvement E is not correct that the estimated S622 is readjusted and the process 600b is repeated. The device-yielding shaping conditions may be used by the shaping process 300 to generate device-yielding substrates. These device-yielding substrates may be processed in processing step S312 to yield devices (articles).

### Bowing Out of Template During Contacting Period

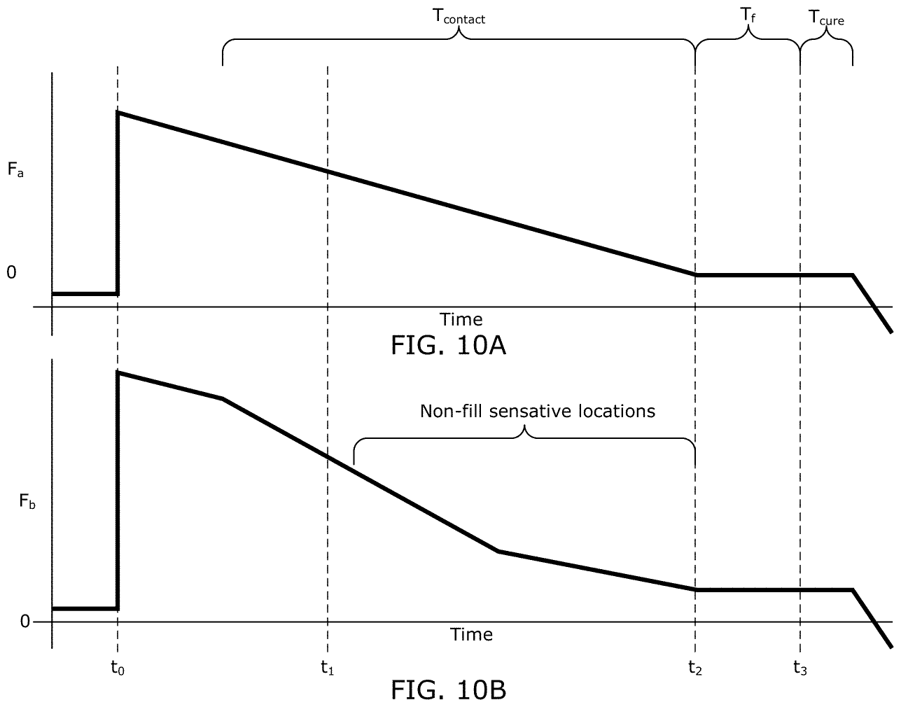

FIG. 9A illustrates a template 108 at a time t₀ held by the template chuck 118 after the dispensing period T_{d} and prior to the contacting period T_{contact}; in which the template is bowed out by a back pressure P(t₀); and is held above the formable material 124 on the substrate 102 at a height z(t₀). FIG. 9B illustrates a template 108 at a time t₁ held by the template chuck 118 at the beginning of the contacting period T_{contact}; in which the template is bowed out by a back pressure P(t₁); an initial portion of the shaping surface 112 is in contact with a portion of the formable material 124 on the substrate 102 at a height z(t₁); and a force F(t₁) is supplied by actuators to a back surface of the template chuck 118. FIG. 9C illustrates a template 108 at a time t₂ held by the template chuck 118 during the contacting period T_{contact}; in which the template is bowed out by a back pressure P(t₂); a portion of the shaping surface 112 is in contact with a portion of the formable material 124 on the substrate 102 at a height z(t₂); and a force F(t₂) is supplied by actuators to a back surface of the template chuck 118. FIG. 9D illustrates a template 108 at a time t₃ held by the template chuck 118 at the end of the contacting period T_{contact} and the beginning of the filling period T_{f}; in which the template is not bowed out by a back pressure P(t₃); the shaping surface 112 is in contact with the formable material 124 on the substrate 102 at a height z(t₃); and a force F(t₃) is supplied by actuators to a back surface of the template chuck 118.

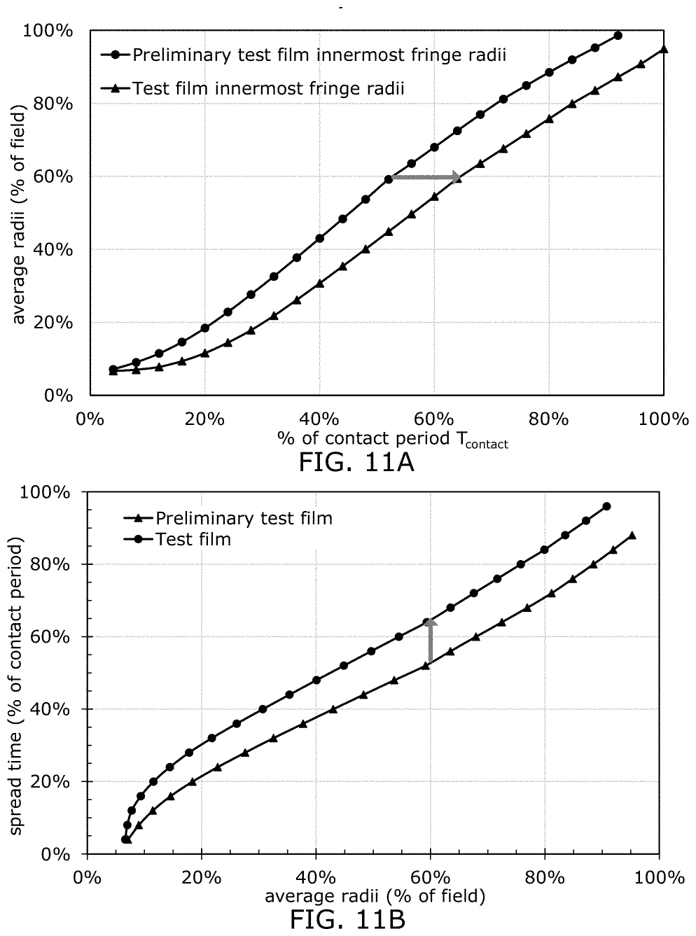

FIG. 10A is a chart illustrating a preliminary force trajectory Fₐ during the contacting period T_{contact}, the filling period T_{f}, and the curing period T_{cure} as might be used in forming the short fill time preliminary test film and the long fill time preliminary test film in the correlation set generation process 600a. FIG. 10B is a chart illustrating a test force trajectory F_{b} which may be used in the shaping condition optimization process 600b for forming a test film with the test shaping conditions. When the non-fill sensitive locations are near the edge of the shaping field rather than near the center then greater force may be used initially and then less force latter on as illustrated in FIG. 10B relative to FIG. 10A.

FIGS. 11A-D are charts illustrating spreading characteristics obtained from images obtained while forming preliminary test films and test films. FIG. 11A is a chart showing the average radii of the innermost fringe during the contacting period T_{contact} for the short fill time preliminary test film and the test film as a percent of the field. The percent of the field means relative to a radius from the center of the shaping field to the farthest corner of the shaping field. The expected improvement E at a specific radii (for example 60% of the field) may be estimated based on a difference (illustrated by the gray arrow in FIG. 11A) between the average radii for short fill time preliminary test film and the test film. The specific radii may be associated with non-fill sensitive location as determined for example by the data in FIG. 5C. If this difference is above an expected improvement threshold E_{T} then shaping conditions for the test film is estimated be an improvement of the shaping conditions for the short fill time preliminary test film. Data may be interpolated to determine the improvement at specific radii.

FIG. 11B is a chart showing how the spread time as a percent of changes in the imprint field changes with time, this is just a rotation of the data presented in FIG. 11C, and the analysis is the same as for FIG. 11A.

FIG. 11C is a chart showing a difference between the average radii of the innermost fringe and second innermost fringe as a percent of shaping field as a function of percent of the contacting period T_{contact} for the short fill time preliminary test film and the test film as a percent of the field. This may be converted to contact angle using equation (1) above and instead of contacting period the estimated contact radius may be used as illustrated in FIG. 11D. Note that at 60% there is only a small improvement in the contact angle as illustrated by the grey arrow in FIG. 11D.

In an embodiment, the expected improvement E may be determined as a weighted sum of changes in multiple different spreading characteristics. The above example was shown with data which was averaged over the radius, but this is not a necessary step and information may be gathered instead at specific non-fill sensitive locations.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method of shaping a film comprising:
shaping the film with a template;
analyzing a time series of images obtained by imaging the film while shaping the film to estimate film spreading characteristics; and
creating an estimate of a probable reduction in non-fill defects based on the film spreading characteristics.

2. The method of claim 1, further comprising presenting the film spreading characteristics on a display device and the estimate of the probable reduction in non-fill defects.

3. The method of claim 1, further comprising determining a shaping condition based on the estimate of the probable reduction in non-fill defects.

4. A method of manufacturing an article using the method of claim 3, further comprising:
shaping a device-yielding film on a device-yielding substrate with the determined shaping condition;
processing the device-yielding substrate; and
forming the article from the processed device-yielding substrate.

5. The method of claim 1, wherein shaping the film comprises:
dispensing a drop pattern of drops of formable material onto a substrate;
bowing out the template with an initial back pressure prior to an initial contact time;
at the initial contact time, positioning the bowed out template at an initial contact position, wherein at the initial contact time, a portion of the bowed out template is in contact with a portion of the drops of formable material;
during a first contact period, starting with the initial contact time, reducing back pressure applied to the template along a back pressure trajectory;
during the first contact period, reducing a force applied to the template along a force trajectory;
during a filling period, after the contact period, holding the back pressure and the force applied to the template substantially constant;
during a curing period, after the filling period, exposing the formable material to actinic radiation.

6. The method of claim 1, further comprises:
shaping a pair of preliminary test films;
wherein the pair of preliminary test films includes: a short fill time preliminary test film; and a long fill time preliminary test film;
wherein the short fill time preliminary test film is shaped with a first subset of shaping conditions and a short fill time;
wherein the long fill time preliminary test film is shaped with the first subset of shaping conditions and a long fill time;
generating a pair of preliminary maps of non-fill defect density of the pair of preliminary test films;
wherein the pair of preliminary maps includes: a short fill time map; and a long fill time map;
identifying a set of non-fill sensitive locations as locations in the pair of preliminary maps with a defect density above a threshold in the short fill time map and defect density below the threshold in the long fill time map;
analyzing a preliminary series of images obtained by imaging the short fill time preliminary test film while shaping the short fill time preliminary test film to estimate a set of preliminary test film spreading characteristics;
generating a correlation set comprising: the set of non-fill sensitive locations; and the set of preliminary test film spreading characteristics.

7. The method of claim 6, wherein a set of shaping conditions is used while shaping the film that is used for creating the estimate of the probable reduction in non-fill defects; the set of shaping conditions includes a first variation of the first subset of shaping conditions and the short fill time.

8. The method of claim 7, wherein creating the estimate of the probable reduction in non-fill defects comprises:
calculating a set of spreading characteristic differences between a set of the film spreading characteristics and the set of preliminary test film spreading characteristics at the set of non-fill sensitive locations.

9. The method of claim 8, wherein creating the set of preliminary test film spreading characteristics comprises:
comparing the set of spreading characteristic differences to a threshold.

10. The method of claim 7, further comprises determining if the first variation is an improvement on the first subset of shaping conditions and the short fill time, based on the map of non-fill defect expected improvement.

11. The method of claim 7, wherein the first variation of the first subset of shaping conditions includes an adjustment of one or both of: an imprint force trajectory; and an imprint backpressure trajectory.

12. The method of claim 6, wherein generating pairs of preliminary maps comprises:
inspecting the short fill time preliminary test film to identify locations of non-fill defects which makes up the short fill time map; and
inspecting the long fill time preliminary test film to identify locations of non-fill defects which makes up the long fill time map; and
the method further comprising:
generating a short fill time radial histogram of defect density by azimuthally averaging defects in the short fill time map; and
generating a long fill time radial histogram of defect density by azimuthally averaging defects in the long fill time map; and
wherein the set of non-fill sensitive locations are a set of non-fill sensitive radial regions in which a difference between the long fill time radial histogram and the short fill time radial histogram are above a defect density threshold;
wherein generating the correlation set comprises identifying a set of non-fill sensitive spread times based on the set of preliminary test film spreading characteristics that correspond to the set of non-fill sensitive radial regions.

13. The method of claim 12, wherein the set of preliminary test film spreading characteristics includes a preliminary time series of radially averaged estimated contact radii; and
wherein identifying the set of non-fill sensitive spread times comprises identifying time periods in the time series of radially averaged estimated contact radii in which the radially averaged estimated contact radii are within the set of non-fill sensitive radial regions.

14. The method of claim 13, wherein a first set of shaping conditions is used for shaping the film that is used for creating the estimate of the probable reduction in non-fill defects; the first set of shaping conditions includes a variation of the first subset of shaping conditions;
wherein the variation includes an adjustment to one or both of a back pressure trajectory and a force trajectory in the first subset of shaping conditions during at least one time period in the set of non-fill sensitive spread times.

15. The method of claim 6, wherein the set of preliminary test film spreading characteristics includes a set of preliminary spread times correlated with a preliminary set of radially averaged estimated contact radii;
wherein the film spreading characteristics includes a set of test spread times correlated with a test set of radially averaged estimated contact radii;
the method may further comprise calculating spread time differences between:
the set of test spread times at the set of non-fill sensitive locations in the test set of radially averaged estimated contact radii; and
the set of preliminary spread times at the set of non-fill sensitive locations in the preliminary set of radially averaged estimated contact radii;
wherein the estimate of the probable reduction in non-fill defects is based on the spread time differences.

16. The method of claim 6, wherein the set of preliminary test film spreading characteristics includes a preliminary set of radially averaged estimated contact angles correlated with a preliminary set of radially averaged estimated contact radii;
wherein the film spreading characteristics includes a test set of radially averaged estimated contact angles correlated with a test set of radially averaged estimated contact radii;
the method may comprise calculating contact angle differences between:
the test set of radially averaged estimated contact angles at the set of non-fill sensitive locations in the test set of radially averaged estimated contact radii; and
the preliminary set of radially averaged estimated contact angles at the set of non-fill sensitive locations in the preliminary set of radially averaged estimated contact radii;
wherein the estimate of the probable reduction in non-fill defects is based on the contact angle differences.

17. A method of determining shaping conditions for shaping a film comprising:
(a) shaping a film in a plurality of fields with a plurality of shaping conditions including short spread times below a threshold and long spread times above the threshold;
(b) analyzing the plurality of fields to identify a first set of locations in which non-fill defects appear during short spread times and do not appear during long spread times;
(c) determining a first set of spread speeds and a first set of contact angles for each of the first set of location and for each of the plurality of shaping conditions by analyzing a time series of images obtained by imaging the film in the plurality of fields during the shaping of the plurality of fields;
(d) shaping a film in a test field with a set of test shaping conditions;
(e) determining a test set of spread speeds and a test set of contact angles for each of the first set of locations by analyzing a test series of images obtained by imaging the film in the test field during the shaping of the test field with the test shaping conditions;
(f) determining a test expected improvement that there are one or more non-fill defects at the first set of locations based on: the test set of spread speeds; the test set of contact angles; the first set of spread speeds; and the first set of contact angles; and
(g) repeat steps (d)-(f) with different test shaping conditions to identify test shaping conditions with the lowest test expected improvement as the shaping conditions.

18. A shaping system control apparatus comprising:
a memory; and
a processor;
wherein the processor is configured to:
send a shaping condition to a shaping system, wherein the shaping system will shape a film with the shaping condition;
receive a time series of images from the shaping system that were obtained by imaging the film while shaping the film and store the time series of images in the memory;
analyze the time series of images to estimate a film spreading characteristics; and
create an estimate of a probable reduction in non-fill defects based on the film spreading characteristics.
